(19) United States
(12) Patent Application Publication
(10) Pub. No.: US 2014/0313671 A1
(43) Pub. Date: Oct. 23, 2014

(54) POWER CONVERSION APPARATUS

(71) Applicants: Masayuki SUGITA, Toyota-shi (JP); Takashi ATSUMI, Toyota-shi (JP); Shinichi MIURA, Toyota-shi (JP)

(72) Inventors: Masayuki SUGITA, Toyota-shi (JP); Takashi ATSUMI, Toyota-shi (JP); Shinichi MIURA, Toyota-shi (JP)

(73) Assignee: TOYOTA JIDOSHA KABUSHIKI KAISHA, Toyota-shi (JP)

(21) Appl. No.: 14/248,674

(22) Filed: Apr. 9, 2014

(30) Foreign Application Priority Data
Apr. 17, 2013 (JP) 2013-086835

(51) Int. Cl. H05K 7/20

(52) U.S. Cl. CPC H05K 7/2029
USPC 361/700

(57) ABSTRACT

A power conversion apparatus includes a refrigerant supply and discharge portion and a laminated body. The refrigerant supply and discharge portion performs supply and discharge of refrigerant with respect to the cooler. The refrigerant supply and discharge portion is placed on a first end face of the laminated body, the first end face intersecting with a first vertical direction vertical to a laminating direction in the laminated body. One of the terminal portion and the electrode terminal of the semiconductor module is placed on a second end face of the laminated body, the second end face intersecting with the first vertical direction.

### INCORPORATION BY REFERENCE

The disclosure of Japanese Patent Application No. 2013-086835 filed on Apr. 17, 2013 including the specification, drawings and abstract is incorporated herein by reference in its entirety.

### BACKGROUND OF THE INVENTION

1. Field of the Invention

The present invention relates to a power conversion apparatus provided with a laminated body in which a semiconductor module, a capacitor, and a cooler are laminated.

2. Description of Related Art

In Japanese Patent Application Publication No. 2001-320005 (JP 2001-320005 A), a laminated body in which a semiconductor module, a capacitor, and a refrigerant tube are laminated is provided, a refrigerant supply portion that supplies refrigerant into the refrigerant tube is placed on one end face of the laminated body in a direction vertical to a laminating direction, and a refrigerant discharge portion that discharges the refrigerant from the refrigerant tube is placed on the other end face of the laminated body in the direction vertical to the laminating direction.

### SUMMARY OF THE INVENTION

On an outer surface of the laminated body, it is necessary to place various components such as the refrigerant supply portion that supplies refrigerant, the refrigerant discharge portion that discharges the refrigerant, a terminal portion connected to a power supply, a wiring member that connects an electrode terminal of the semiconductor module, the capacitor, and the terminal portion to each other, and the like. In JP 2001-320005 A, since the refrigerant supply portion and the refrigerant discharge portion are placed respectively on the one end face and the other end face of the laminated body in the direction vertical to the laminating direction, it is necessary to place the terminal portion and the electrode terminal of the semiconductor module on respective planes opposed to each other with the laminated body sandwiched therebetween, which makes it difficult to attain space-saving by reducing a size. Further, an electric path length to connect them is long, so that it is difficult to attain low inductance.

The present invention provides a power conversion apparatus in which a semiconductor module, a capacitor, and a cooler are laminated and which devises an arrangement of a refrigerant supply portion, a refrigerant discharge portion, a terminal portion, and an electrode terminal of the semiconductor module, thereby realizing spacing-saving and realizing low inductance by shortening an electric path length.

A power conversion apparatus according to a first aspect of the present invention includes a cooler, a refrigerant supply and discharge portion, a semiconductor module, a capacitor, a terminal portion, an electrode terminal, and a wiring member. The refrigerant supply and discharge portion performs supply and discharge of refrigerant with respect to the cooler. The semiconductor module, the capacitor, and the cooler are laminated so as to constitute a laminated body. The refrigerant supply and discharge portion is placed on a first end face of the laminated body, the first end face intersecting with a first vertical direction vertical to a laminating direction in the laminated body. The terminal portion is connected to a power supply. The electrode terminal is provided in the semiconductor module. One of the terminal portion and the electrode terminal of the semiconductor module is placed on a second end face of the laminated body, the second end face intersecting with the first vertical direction. The other of the terminal portion and the electrode terminal of the semiconductor module is placed on a third end face of the laminated body, the third end face intersecting with a second vertical direction vertical to the laminating direction and the first vertical direction. The wiring member connects the electrode terminal to the capacitor and the terminal portion.

In the above aspect, the semiconductor module and the capacitor may be placed adjacent to each other via the cooler in the laminating direction.

In the above aspect, a reactor may be further laminated in the laminated body, and the reactor may be placed at an end portion intersecting with the laminating direction than the semiconductor module and the capacitor.

In the above aspect, the refrigerant supply and discharge portion may be provided with a refrigerant supply port communicating with a refrigerant passage of the cooler so as to supply coolant to the refrigerant passage of the cooler, and the refrigerant supply and discharge portion may be provided with a refrigerant discharge port communicating with the refrigerant passage of the cooler so as to discharge the coolant from the refrigerant passage of the cooler.

In the above aspect, the capacitor may include a filter capacitor and a smoothing capacitor, and the filter capacitor may be placed closer to the second end face of the laminated body than the smoothing capacitor.

According to the above aspect, the refrigerant supply and discharge portion performing supply and discharge of refrigerant with respect to the cooler is placed on the first end face of the laminated body, the first end face intersecting with the first vertical direction. Hereby, the second end face intersecting with the first vertical direction is vacant. Therefore one of the terminal portion connected to the power supply and the electrode terminal of the semiconductor module is placed on the second end face, and the other of the terminal portion connected to the power supply and the electrode terminal of the semiconductor module is placed on the third end face which is adjacent to the second end face intersecting with the first vertical direction and which intersects with the second vertical direction. This makes it possible to realize spacing-saving, and to realize low inductance by reducing an electric path length of a wiring member that connects the terminal portion and the capacitor to the electrode terminal of the semiconductor module.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a circuit diagram illustrating an example of a configuration of an electric motor driving system including a power conversion apparatus according to an embodiment of the present invention;

FIG. 2 is a perspective view illustrating a structure of the power conversion apparatus according to the present embodiment;

FIG. 3 is a perspective view illustrating the structure of the power conversion apparatus according to the present embodiment;

FIG. 4 is a perspective view illustrating the structure of the power conversion apparatus according to the present embodiment;

FIG. 5 is a perspective view to describe a three-dimensional coordinate system that defines a laminated body;

FIG. 6 is a perspective view illustrating an example of a structure in which an electrode terminal of a booster power card is connected to a reactor via a bus bar;

FIG. 7 is a perspective view illustrating an example of a structure in which an electrode terminal of the booster power card is connected to a smoothing capacitor via a bus bar;

FIG. 8 is a perspective view illustrating an example of a structure in which an electrode terminal of an inverter power card is connected to the smoothing capacitor via a bus bar;

FIG. 9 is a perspective view illustrating an example of a structure in which an electrode terminal of the booster power card is connected to the smoothing capacitor via a bus bar;

FIG. 10 is a perspective view illustrating an example of a structure in which an electrode terminal of the inverter power card is connected to the smoothing capacitor via a bus bar;

FIG. 11 is a perspective view illustrating an example of a structure in which a filter capacitor is connected to the smoothing capacitor; and

FIG. 12 is a perspective view illustrating an example of a structure of the electrode terminal of the inverter power card.

### DETAILED DESCRIPTION OF EMBODIMENTS

An embodiment of the present invention is described below with reference to the drawings.

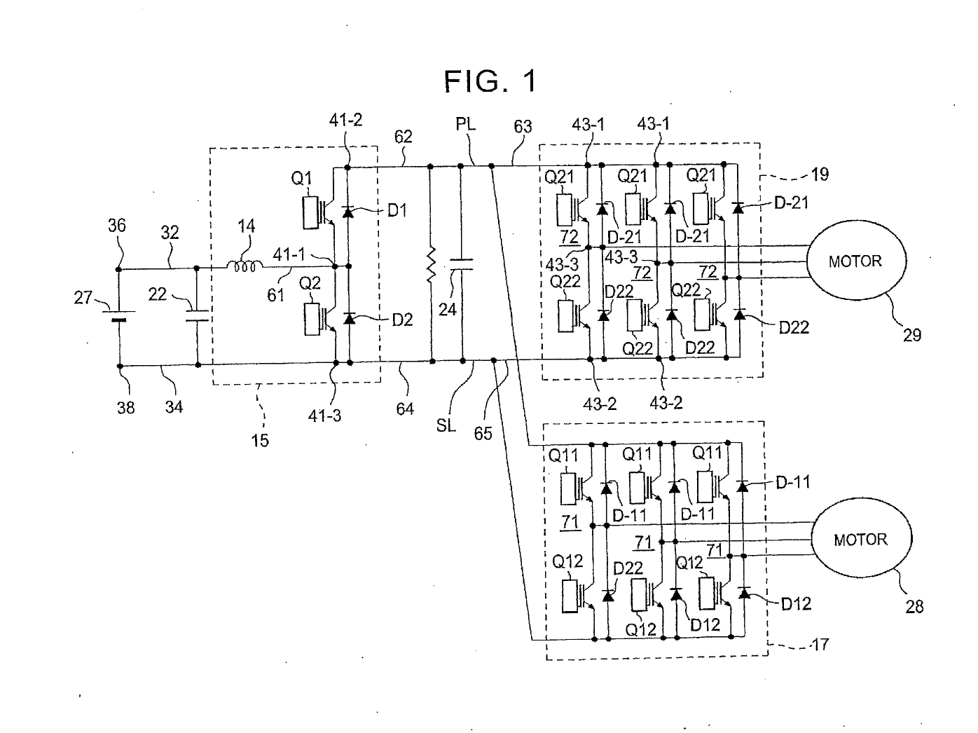

FIG. 1 is a circuit diagram illustrating an example of a configuration of an electric motor driving system including a power conversion apparatus according to the embodiment of the present invention. The electric motor driving system according to the present embodiment is usable, for example, for a drive system for a vehicle. As illustrated in FIG. 1, the electric motor driving system includes: a secondary battery 27 as a direct-current power supply that is chargeable and dischargeable; a DC-DC converter (a boost converter) 15 that converts a direct-current power from the secondary battery 27 into a direct-current power having a different voltage value and outputs the direct-current power; a filter capacitor 22 provided on an input side of the DC-DC converter 15; inverters 17, 19 that convert a direct-current power from the DC-DC converter 15 into an alternating current and outputs the alternating current; a smoothing capacitor 24 provided on an input side (an output side of the DC-DC converter 15) of the inverters 17, 19; and motor generators 28, 29 that receive an alternating current from the inverters 17, 19 so as to be rotationally driven.

The DC-DC converter 15 includes two switching elements Q1, Q2 connected in series to each other so that they are provided respectively on a source side and a sink side relative to a positive side line PL and a negative side line SL of the inverters 17, 19; two diodes D1, D2 respectively connected in reverse-parallel to the switching elements Q1, Q2; and a reactor 14 of which one end is connected to one end (a positive-side terminal) of the secondary battery 27 and the other end is connected to a connecting point between the switching elements Q1, Q2. Each of the switching elements Q1, Q2 is constituted by a semiconductor element such as IGBT, for example. The switching element Q1 is placed between the other end of the reactor 14 and an output end (the positive-side line PL of the inverters 17, 19) of the DC-DC converter 15. The switching element Q2 is placed between the other end of the reactor 14 and the other end (a negative-side terminal) of the secondary battery 27. The DC-DC converter 15 is configured such that, when the switching element Q2 is turned on, a short-circuit that connects the secondary battery 27, the reactor 14, and the switching element Q2 with each other is formed, so that an energy is temporarily accumulated in the reactor 14 according to a direct current flowing from the secondary battery 27. In this state, when the switching element Q2 is turned off from its on state, the energy accumulated in the reactor 14 is accumulated in the smoothing capacitor 24 via the diode D1. On this occasion, a direct voltage (an output voltage of the DC-DC converter 15) of the smoothing capacitor 24 can be increased to be higher than a direct voltage (an input voltage of the DC-DC converter 15) of the secondary battery 27. Accordingly, the DC-DC converter 15 functions as a boost converter that boosts up a direct-current power input from the secondary battery 27 and outputs it to the inverters 17, 19. Meanwhile, the DC-DC converter 15 is able to charge the secondary battery 27 by use of an electric charge of the smoothing capacitor 24.

The filter capacitor 22 is provided in parallel with the secondary battery 27 on the input side of the DC-DC converter 15. A capacity of the filter capacitor 22 is smaller than a capacity of the smoothing capacitor 24. At the time of a switching operation of the switching elements Q1, Q2, a ripple component is caused in a current flowing through the reactor 14. When the filter capacitor 22 is provided in parallel with the secondary battery 27, the current flowing through the reactor 14 is a current obtained by superposing a current (a direct-current component) of the secondary battery 27 with a current (a ripple component) of the filter capacitor 22. As a result a current variation of the secondary battery 27 is restrained.

The inverter 17 includes a plurality of (three, in FIG. 1) arms 71 connected in parallel with each other between the positive-side line PL and the negative-side line SL. Each of the arms 71 includes a pair of switching elements Q11, Q12 connected in series to each other between the positive-side line PL and the negative-side line SL, and a pair of diodes D11, D12 respectively connected in reverse-parallel to the switching elements Q11, Q12. A coil (a three-phase coil) of the motor generator 28 is connected to a middle point of each of the arms 71. The inverter 17 converts a direct-current power input from the DC-DC converter 15 into a three-phase alternating current of which phases are different from each other by 120°, by a switching operation of the switching elements Q11, Q12, and then supplies the three-phase alternating current to the three-phase coil of the motor generator 28. Hereby, the motor generator 28 can be rotationally driven. In the meantime, it is also possible for the inverter 17 to convert an alternating-current power of the three-phase coil of the motor generator 28 into a direct current and to supply the direct current to the DC-DC converter 15.

The inverter 19 has the same configuration as the inverter 17. The inverter 19 includes a plurality of (three, in FIG. 1) arms 72 each including switching elements Q21, Q22 and diodes D21, D22, and a three-phase coil of the motor generator 29 is connected to a middle point of each of the arms 72. The inverter 19 also converts a direct-current power input from the DC-DC converter 15 into a three-phase alternating current by a switching operation of the switching elements Q21, Q22, and then supplies the three-phase alternating current to the three-phase coil of the motor generator 29. Hereby, the motor generator 29 can be rotationally driven. In the meantime, it is also possible for the inverter 19 to convert an alternating-current power of the three-phase coil of the motor generator 29 into a direct current and to supply the direct current to the DC-DC converter 15.

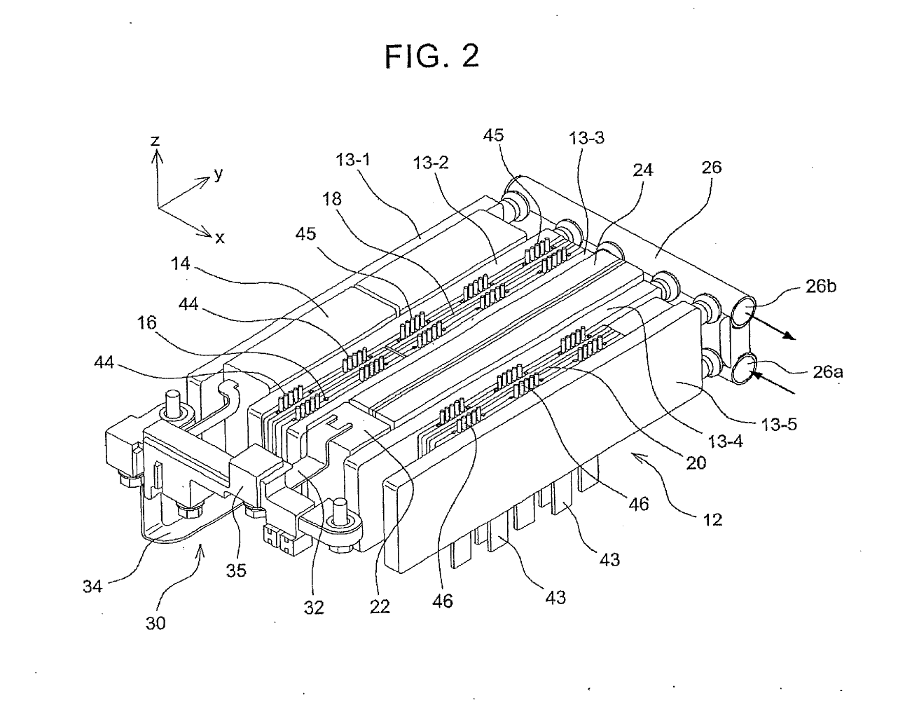

Next will be described a structure of the power conversion apparatus according to the present embodiment. FIGS. 2 to 4 are perspective views illustrating the structure of the power conversion apparatus according to the present embodiment. The power conversion apparatus according to the present embodiment includes a laminated body 12 in which inverter power cards 18, 20, a booster power card 16, the filter capacitor 22, the smoothing capacitor 24, the reactor 14, and a plurality of cooling plates 13-1 to 13-5 are laminated. A direction in which respective members are laminated in the laminated body 12 is taken as a laminating direction. When a xyz three-dimensional coordinate system in which the laminating direction of the laminated body 12 is taken as an x-axis is defined as illustrated in FIGS. 2 to 4, these members in an example of the laminated body 12 illustrated in FIGS. 2 to 4 are laminated in the order of the cooling plate 13-1, the reactor 14, the cooling plate 13-2, the booster power card 16 and the inverter power card 18, the cooling plate 13-3, the filter capacitor 22 and the smoothing capacitor 24, the cooling plate 13-4, the inverter power card 20, and the cooling plate 13-5, as it goes from a negative side to a positive side in the x-axis. When the laminated body 12 is formed, the laminated body 12 is pressed by acting, on the laminated body 12, a compressive load from an x-axis negative side to an x-axis positive side.

The booster power card 16 is a semiconductor module on which the switching elements Q1, Q2 and the diodes D1, D2 are provided, and forms a circuit for the DC-DC converter (a boost converter) 15 illustrated in FIG. 1, together with the reactor 14. The booster power card 16 is provided with a plurality of electrode terminals 41 that input and output an electric power to the switching elements Q1, Q2 and the diodes D1, D2, and a plurality of control terminals 44 that perform a switching control on the switching elements Q1, Q2. The inverter power card 18 is a semiconductor module on which the switching elements Q11, Q12 and the diodes D11, D12 are provided, and forms a circuit for the inverter 17 illustrated in FIG. 1. The inverter power card 18 is provided with a plurality of electrode terminals that input and output an electric power to the switching elements Q11, Q12 and the diodes D11, D12, and a plurality of control terminals 45 that perform a switching control on the switching elements Q11, Q12. The inverter power card 20 is a semiconductor module on which the switching elements Q21, Q22 and the diodes D21, D22 are provided, and forms a circuit for the inverter 19 illustrated in FIG. 1. The inverter power card 20 is provided with a plurality of electrode terminals 43 that input and output an electric power to the switching elements Q21, Q22 and the diodes D21, D22, and a plurality of control terminals 46 that perform a switching control on the switching elements Q21, Q22. A control voltage from a control circuit (not shown) is input into each of the control terminals 44, 45, 46.

Inside each of the cooling plates 13-1 to 13-5 provided as a cooler, a refrigerant passage through which refrigerant such as coolant flows is formed. The reactor 14 is sandwiched between the cooling plates 13-1, 13-2 in the laminating direction (the x-axis direction), and cooling of the reactor 14 is performed from both sides of the reactor 14 by the coolant flowing through the refrigerant passages inside the cooling plates 13-1, 13-2. The booster power card 16 and the inverter power card 18 are sandwiched between the cooling plates 13-2, 13-3 in the laminating direction, so that cooling of the booster power card 16 (the switching elements Q1, Q2) and the inverter power card 18 (the switching elements Q11, Q12) is performed from both sides of the booster power card 16 (the switching elements Q1, Q2) and the inverter power card 18 (the switching elements Q11, Q12) by the coolant flowing through the refrigerant passages inside the cooling plates 13-2, 13-3. The filter capacitor 22 and the smoothing capacitor 24 are sandwiched between the cooling plates 13-3, 13-4 in the laminating direction. And cooling of the filter capacitor 22 and the smoothing capacitor 24 is performed from both sides of the filter capacitor 22 and the smoothing capacitor 24 by the coolant flowing through the refrigerant passages in the cooling plates 13-3, 13-4. The inverter power card 20 is sandwiched between the cooling plates 13-4, 13-5 in the laminating direction. And cooling of the inverter power card 20 (the switching elements Q21, Q22) is performed from both sides of the inverter power card 20 (the switching elements Q21, Q22) by the coolant flowing through the refrigerant passages in the cooling plates 13-4, 13-5.

A refrigerant supply and discharge pipe 26 performs supply and discharge of the coolant with respect to each of the cooling plates 13-1 to 13-5. The refrigerant supply and discharge pipe 26 is provided with a refrigerant supply port 26a that communicates with the refrigerant passage of each of the cooling plates 13-1 to 13-5 so as to supply the coolant to the refrigerant passage, and a refrigerant discharge port 26b that communicates with the refrigerant passage of each of the cooling plates 13-1 to 13-5 so as to discharge the coolant from the refrigerant passage.

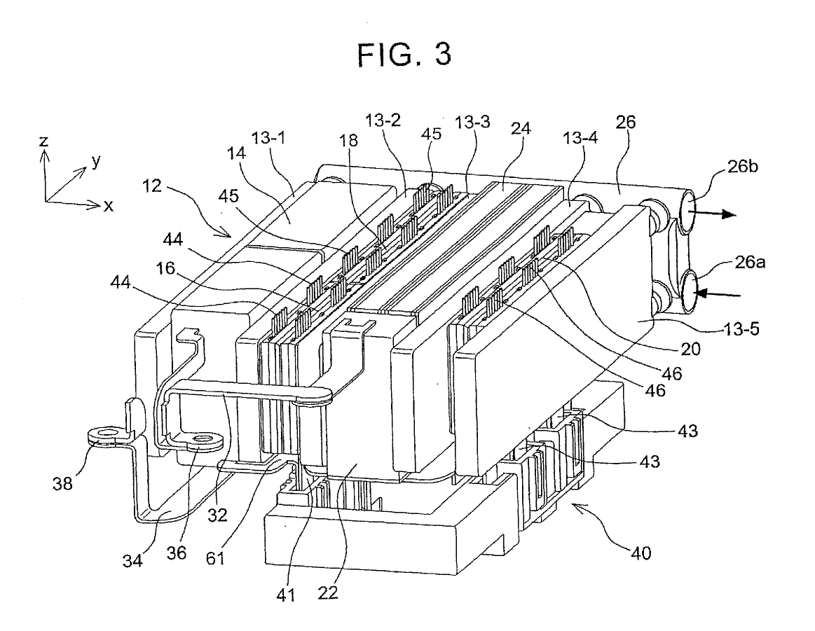

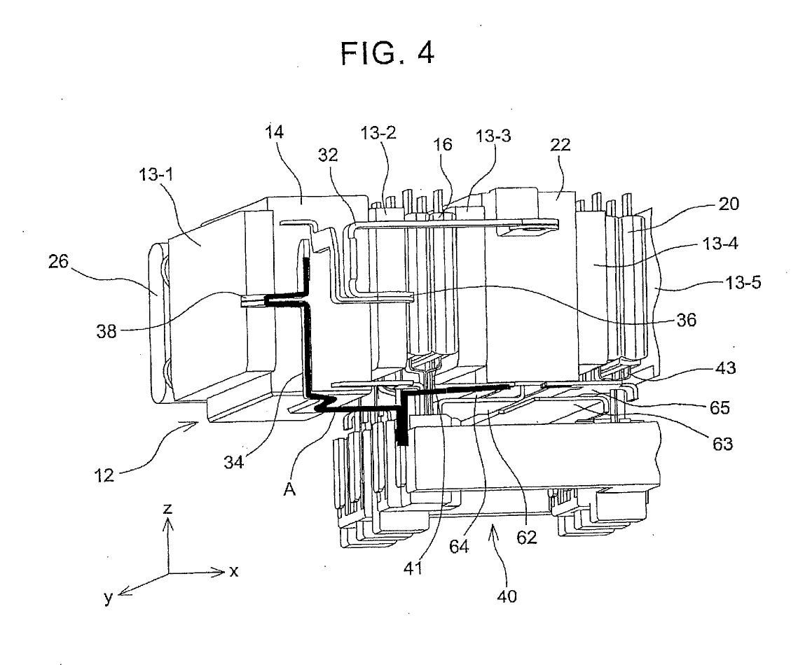

A terminal block 30 includes a resin housing 35, a positive-side bus bar 32 fixed to the resin housing 35, and a negative-side bus bar 34 fixed to the resin housing 35 in a state where the negative-side bus bar 34 is electrically insulated from the positive-side bus bar 32. The positive-side bus bar 32 is provided with a positive-side terminal 36 electrically connected to the positive-side terminal of the secondary battery 27 serving as a power supply, the negative-side bus bar 34 is provided with a negative-side terminal 38 electrically connected to the negative-side terminal of the secondary battery 27, and a direct-current power from the secondary battery 27 is supplied to the positive-side terminal 36 of the positive-side bus bar 32 and the negative-side terminal 38 of the negative-side bus bar 34. In FIGS. 3, 4, the resin housing 35 is not illustrated herein.

A main wiring module 40 includes a plurality of bus bars as wiring members. The plurality of bus bars electrically connects the electrode terminals 41 of the booster power card 16, the electrode terminals of the inverter power card 18, and the electrode terminals 43 of the inverter power card 20, to the smoothing capacitor 24, the filter capacitor 22, and the negative-side bus bar 34 of the terminal block 30. A detailed description of the bus bars of the main wiring module 40 will be described later. In FIG. 2, the main wiring module 40 is not illustrated.

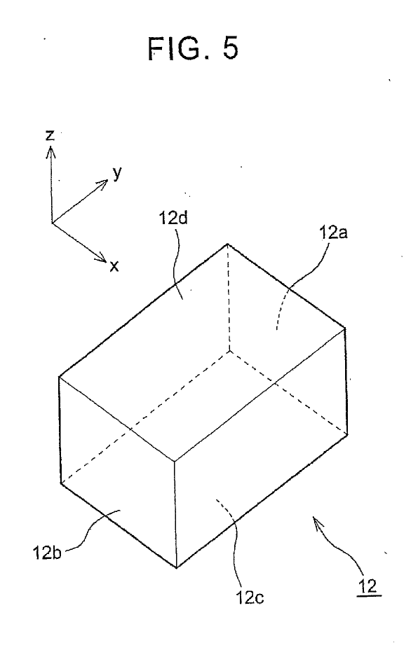

As illustrated in FIG. 5, in the laminated body 12, one end face in a y-axis direction (a first vertical direction) vertical to the x-axis (the laminating direction) is taken as a +y surface 12a, the other end face in the y-axis direction is taken as a −y surface 12b, one end face in a z-axis direction (a second vertical direction) vertical to the x-axis and the y-axis is taken as a −z surface 12c, and the other end face in the z-axis direction is taken as a +z surface 12d. In this case, in the present embodiment, the refrigerant supply and discharge pipe 26 is placed on the +y surface 12a (the one end face in the first vertical direction) in the laminated body 12. The terminal block 30 is placed on the −y surface 12b (the other end face in the first vertical direction) in the laminated body 12, and thus is placed on a reverse face with respect to the +y surface 12a where the refrigerant supply and discharge pipe 26 is placed. The electrode terminals 41 of the booster power card 16, the electrode terminals of the inverter power card 18, the electrode terminals 43 of the inverter power card 20, and the main wiring module 40 are placed on the −z surface 12c (the one end face in the second vertical direction) in the laminated body 12, and thus placed on a surface adjacent to the −y surface 12b where the terminal block 30 is placed. Further, the control terminals 44 of the booster power card 16, the control terminals 45 of the inverter power card 18, the control terminals 46 of the inverter power card 20, and the control circuit (not shown) are placed on the +z surface 12d in the laminated body 12, and thus placed on a reverse face with respect to the −z surface 12c where the electrode terminals 41, 43 and the main wiring module 40 are placed.

The booster power card 16 is placed closer to the −y surface 12b (on a terminal-block-30 side) than the inverter power card 18 in the y-axis direction. The filter capacitor 22 is placed closer to the −y surface 12b (on the terminal-block-30 side) than the smoothing capacitor 24 in the y-axis direction. As illustrated in FIGS. 1, 3, the positive-side bus bar 32 of the terminal block 30 is electrically connected to a positive-side terminal of the filter capacitor 22 and one end of the reactor 14. The filter capacitor 22 is placed on the terminal-block-30 side so as to be electrically connected to the positive-side bus bar 32, and the positive-side bus bar 32 is electrically connected to the reactor 14 on a −y-surface-12b side (on the terminal-block-30 side), thereby making it possible to shorten an electric path length of the positive-side bus bar 32.

Next will be described a configuration of the bus bars of the main wiring module 40. In the following description, in a case where it is necessary to distinguish the plurality of electrode terminals 41 of the booster power card 16, they will be described by use of reference signs 41-1, 41-2, 41-3, and in a case where it is necessary to distinguish the plurality of electrode terminals 43 of the inverter power card 20, they will be described by use of reference signs 43-1, 43-2, 43-3.

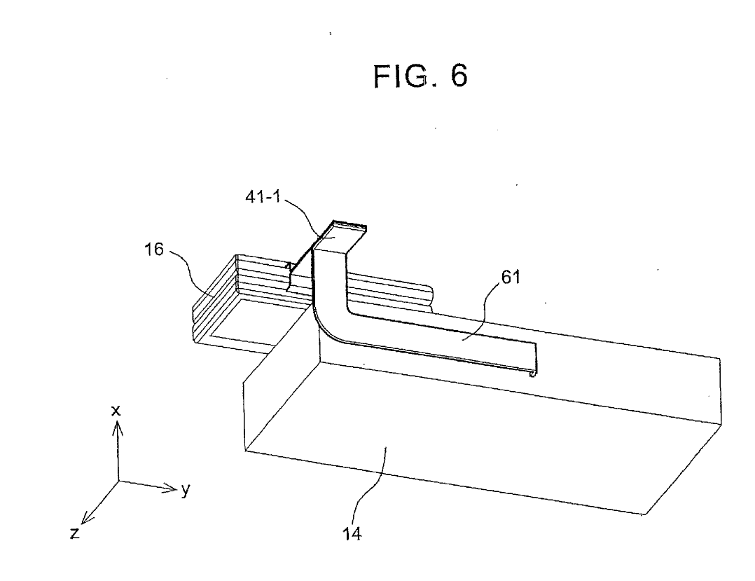

As illustrated in FIGS. 1, 6, the electrode terminal 41-1 of the booster power card 16 is electrically connected to the other end of the reactor 14 via a positive-side bus bar 61 of the main wiring module 40. The electrode terminal 41-1 is an example of a connecting point between the switching elements Q1, Q2 (e.g., a connecting point between an emitter terminal of IGBT and a collector terminal of IGBT) as illustrated in FIG. 1.

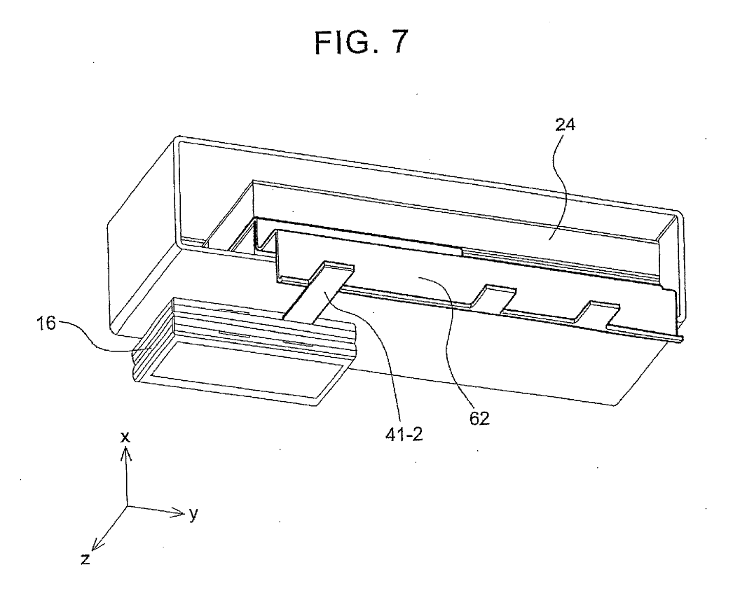

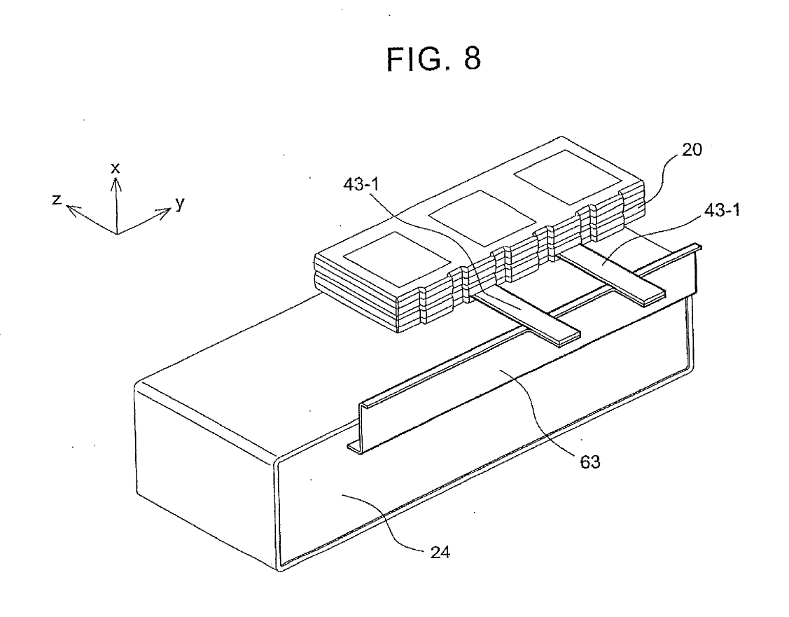

As illustrated in FIGS. 1, 7, the electrode terminal 41-2 of the booster power card 16 is electrically connected to a positive-side terminal of the smoothing capacitor 24 via a positive-side bus bar 62 of the main wiring module 40. As illustrated in FIGS. 1, 8, the electrode terminals 43-1 of the inverter power card 20 are electrically connected to the positive-side terminal of the smoothing capacitor 24 via a positive-side bus bar 63 of the main wiring module 40. Hereby, the electrode terminal 41-2 of the booster power card 16, the positive-side terminal of the smoothing capacitor 24, and the electrode terminals 43-1 of the inverter power card 20 are electrically connected to each other. The positive-side bus bars 62, 63 may be both electrically connected to the positive-side terminal of the smoothing capacitor 24 so that the positive-side bus bars 62, 63 are electrically connected to each other. The positive-side bus bars 62, 63 may be electrically connected to each other so that either one of the positive-side bus bars 62, 63 is electrically connected to the positive-side terminal of the smoothing capacitor 24. As illustrated in FIG. 1, the electrode terminal 41-2 of the booster power card 16 is one example of a collector terminal of the switching element (IGBT) Q1, and the electrode terminal 43-1 of the inverter power card 20 is one example of a collector terminal of the switching element (IGBT) Q21.

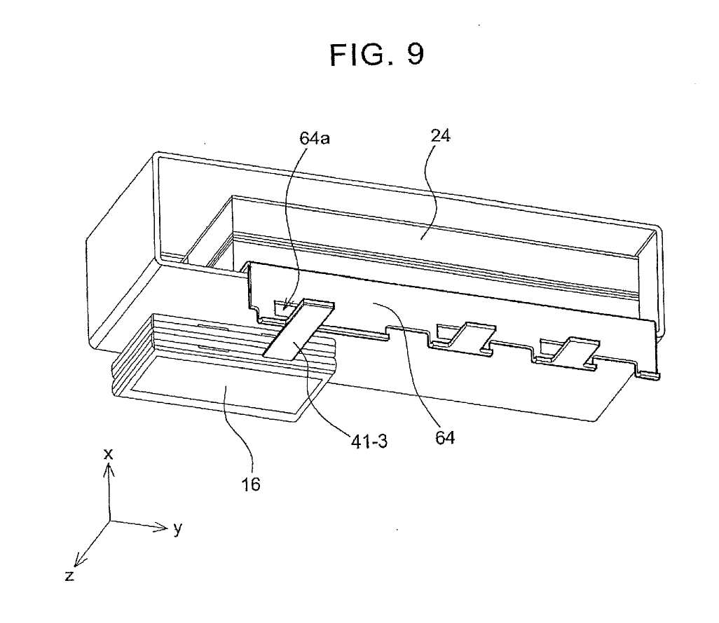

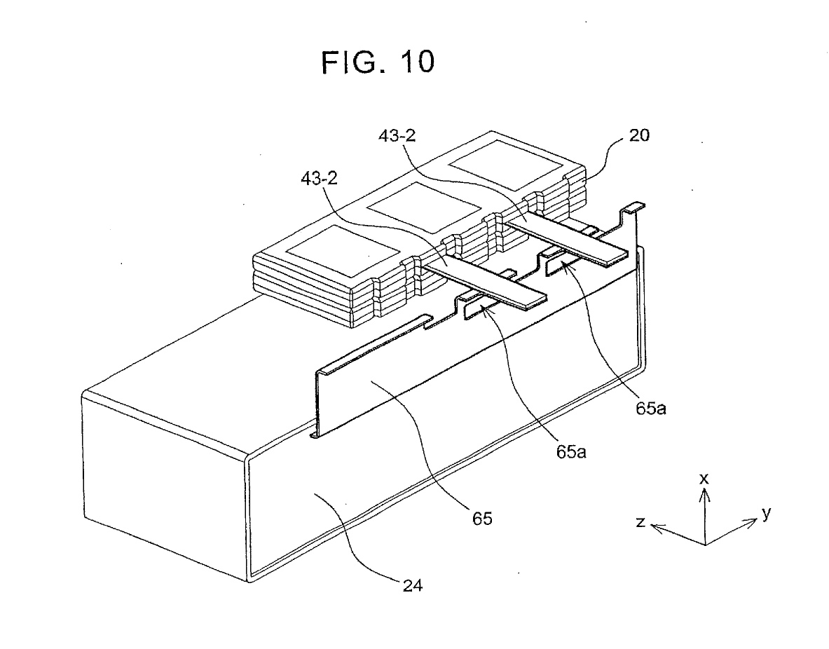

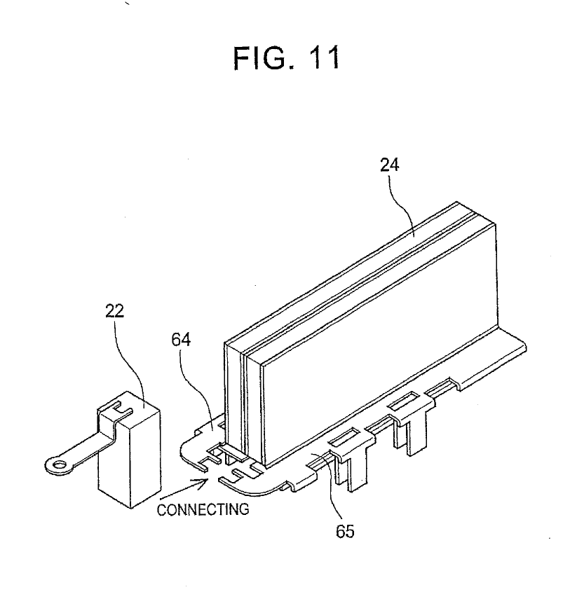

As illustrated in FIGS. 1, 9, the electrode terminal 41-3 of the booster power card 16 is electrically connected to a negative-side terminal of the smoothing capacitor 24 via a negative-side bus bar 64 of the main wiring module 40. As illustrated in FIGS. 1, 10, the electrode terminal 43-2 of the inverter power card 20 is electrically connected to the negative-side terminal of the smoothing capacitor 24 via a negative-side bus bar 65 of the main wiring module 40. Further, as illustrated by a thick line A in FIG. 4, the negative-side bus bar 34 of the terminal block 30 is electrically connected to the negative-side bus bar 64 of the main wiring module 40, and a negative-side terminal of the filter capacitor 22 is electrically connected to the negative-side bus bar 64 of the main wiring module 40. Hereby, the negative-side bus bar 34 of the terminal block 30, the negative-side terminal of the filter capacitor 22, the electrode terminal 41-3 of the booster power card 16, the negative-side terminal of the smoothing capacitor 24, and the electrode terminal 43-2 of the inverter power card 20 are electrically connected to each other. For example, as illustrated in FIG. 11, the negative-side bus bars 64, 65 may be both electrically connected to the negative-side terminal of the filter capacitor 22 so as to electrically connect the negative-side bus bars 64, 65 to each other, and either one of the negative-side bus bars 64, 65 may be electrically connected to the negative-side terminal of the smoothing capacitor 24. This makes it possible to improve simplification, a reduction in copper use amount, and a bus-bar yield rate of the negative-side bus bars 64, 65. Alternatively, the negative-side bus bars 64, 65 may be both electrically connected to the negative-side terminal of the smoothing capacitor 24 so as to electrically connect the negative-side bus bars 64, 65 to each other, and either one of the negative-side bus bars 64, 65 may be electrically connected to the negative-side terminal of the filter capacitor 22. As illustrated in FIG. 1, the electrode terminal 41-3 of the booster power card 16 is one example of an emitter terminal of the switching element (IGBT) Q2, and the electrode terminal 43-2 of the inverter power card 20 is one example of an emitter terminal of the switching element (IGBT) Q22. Further, the negative-side bus bar 64 is placed at a position on a positive side in the z-axis direction compared to the positive-side bus bar 62, and as illustrated in FIG. 9, a hole 64a through which the electrode terminal 41-2 electrically connected to the positive-side bus bar 62 is formed in the negative-side bus bar 64. Further, the negative-side bus bar 65 is placed at a position on a positive side in the z-axis direction compared to the positive-side bus bar 63, and as illustrated in FIG. 10, notches 65a through which the electrode terminals 43-1 electrically connected to the positive-side bus bar 63 are formed in the negative-side bus bar 65.

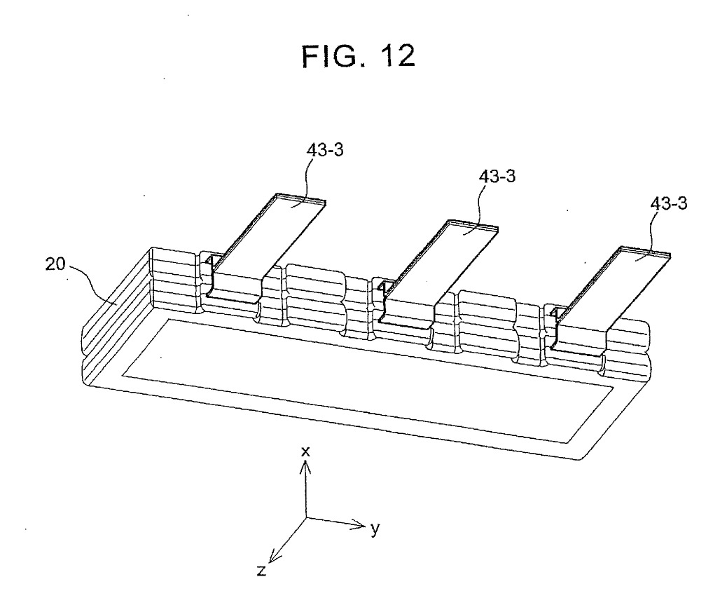

Further, as illustrated in FIGS. 1, 12, the electrode terminals 43-3 of the inverter power card 20 are electrically connected to the coil of the motor generator 29. The electrode terminal 43-3 is an example of that middle point of the arm 72 which is a connecting point between the switching elements Q21, Q22 (e.g., a connecting point between an emitter terminal of IGBT and a collector terminal of IGBT) as illustrated in FIG. 1.

Note that a configuration of that positive-side bus bar of the main wiring module 40 which electrically connects that electrode terminal of the inverter power card 18 which is one example of a collector terminal of the switching element (IGBT) Q11, to the electrode terminal 41-2 of the booster power card 16 and the positive-side terminal of the smoothing capacitor 24 can be realized by the same configuration as the positive-side bus bars 62, 63, so that a description thereof is omitted. Further, a configuration of that negative-side bus bar of the main wiring module 40 which electrically connects that electrode terminal of the inverter power card 18 which is one example of an emitter terminal of the switching element (IGBT) Q12, to the negative-side bus bar 34 of the terminal block 30, the negative-side terminal of the filter capacitor 22, the electrode terminal 41-3 of the booster power card 16, and the negative-side terminal of the smoothing capacitor 24 can be also realized by the same configuration as the negative-side bus bars 64, 65, so that a description thereof is omitted.

According to the present embodiment described above, a refrigerant supply pipe for supplying coolant and a refrigerant discharge pipe for discharging the coolant are combined as the refrigerant supply and discharge pipe 26 and placed on the +y surface 12a (the same surface) of the laminated body 12, so that a space to place the terminal block 30 can be secured on the −y surface 12b (a reverse-side surface with respect to the +y surface 12a) of the laminated body 12. Then, on the −z surface 12c adjacent to the −y surface 12b where the terminal block 30 is placed, the electrode terminals 41 of the booster power card 16, the electrode terminals of the inverter power card 18, the electrode terminals 43 of the inverter power card 20, and the main wiring module 40 are placed. Hereby, it is possible to realize spacing-saving, and in terms of the main wiring module 40 (the negative-side bus bars 64, 65) that electrically connect the electrode terminals 41 of the booster power card 16, the electrode terminals of the inverter power card 18, and the electrode terminals 43 of the inverter power card 20, to the smoothing capacitor 24, the filter capacitor 22, and the terminal block 30 (the negative-side bus bar 34), it is possible to shorten an electric path length without going a long way to pass the control circuit (on the +z surface 12d). Accordingly, a bus-bar use amount of the main wiring module 40 is reduced, thereby making it possible to realize spacing-saving and low inductance.

Further, in the present embodiment, the smoothing capacitor 24 and the inverter power card 20 are placed adjacent to each other via the cooling plate 13-4 in the x-axis direction (the laminating direction). Hereby, it is possible to cool off the smoothing capacitor 24 and the inverter power card 20 by the coolant flowing through the refrigerant passage in the cooling plate 13-4, and to further shorten the electric path length of the main wiring module 40 (the positive-side bus bar 63 and the negative-side bus bar 65) that electrically connects the smoothing capacitor 24 to the electrode terminals 43 of the inverter power card 20. Similarly, since the smoothing capacitor 24 and the booster power card 16 are placed adjacent to each other via the cooling plate 13-3 in the x-axis direction, it is possible to cool off the smoothing capacitor 24 and the booster power card 16 by the coolant flowing through the refrigerant passage in the cooling plate 13-3, and to further shorten the electric path length of the main wiring module 40 (the positive-side bus bar 62 and the negative-side bus bar 64) that electrically connects the smoothing capacitor 10-24 to the electrode terminals 41 of the booster power card 16. Accordingly, the bus-bar use amount of the main wiring module 40 is further reduced, thereby making it possible to realize further spacing-saving and further low inductance.

Further, in the present embodiment, among the reactor 14, the booster power card 16, the inverter power card 18, the inverter power card 20, the filter capacitor 22, and the smoothing capacitor 24, the reactor 14 that has a high rigidity and is wide is placed at one end portion in the laminating direction (an end portion on the x-axis negative side). Hereby, when the laminated body 12 is pressed by acting, on the laminated body 12, a compressive load from the x-axis negative side to the x-axis positive side, it is possible to unify the compressive load to act on the laminated body 12. Further, since the reactor 14 and the booster power card 16 are placed adjacent to each other via the cooling plate 13-2 in the x-axis direction, it is possible to cool off the reactor 14 and the booster power card 16 by the coolant flowing through the refrigerant passage in the cooling plate 13-2, and to further shorten the electric path length of the main wiring module 40 (the positive-side bus bar 61) that electrically connects the reactor 14 to the electrode terminal 41-1 of the booster power card 16.

The embodiment described above deals with a case where the terminal block 30 is placed on the −y surface 12b of the laminated body 12, and the electrode terminals 41 of the booster power card 16, the electrode terminals of the inverter power card 18, the electrode terminals 43 of the inverter power card 20, and the main wiring module 40 are placed on the −z surface 12c of the laminated body 12. However, by replacing the arrangement of the terminal block 30 with the arrangement of the main wiring module 40, it is also possible to place the electrode terminals 41 of the booster power card 16, the electrode terminals of the inverter power card 18, the electrode terminals 43 of the inverter power card 20, and the main wiring module 40 on the −y surface 12b of the laminated body 12, and to place the terminal block 30 on the −z surface 12c of the laminated body 12.

The embodiment of the present invention has been explained as above, but it is needless to say that the present invention is not limited to the above embodiment at all and may be modified in various ways to be performed as long as modified embodiments are not beyond the gist of the present invention.

What is claimed is:

1. A power conversion apparatus comprising:
a cooler;
a refrigerant supply and discharge portion performing supply and discharge of refrigerant with respect to the cooler;
a semiconductor module;
a capacitor,
the semiconductor module, the capacitor, and the cooler being laminated so as to constitute a laminated body, the refrigerant supply and discharge portion being placed on a first end face of the laminated body, and the first end face intersecting with a first vertical direction vertical to a laminating direction in the laminated body;
a terminal portion connected to a power supply;
an electrode terminal provided in the semiconductor module, one of the terminal portion and the electrode terminal of the semiconductor module being placed on a second end face of the laminated body, the second end face intersecting with the first vertical direction, the other of the terminal portion and the electrode terminal of the semiconductor module being placed on a third end face of the laminated body, and the third end face intersecting with a second vertical direction vertical to the laminating direction and the first vertical direction; and
a wiring member connecting the electrode terminal to the capacitor and the terminal portion.

2. The power conversion apparatus according to claim 1, wherein:
the semiconductor module and the capacitor are placed adjacent to each other via the cooler.

3. The power conversion apparatus according to claim 1, further comprising:
a reactor laminated in the laminated body, the reactor being placed at an end portion intersecting with the laminating direction.

4. The power conversion apparatus according to claim 1, wherein:
the refrigerant supply and discharge portion is provided with a refrigerant supply port communicating with a refrigerant passage of the cooler so as to supply coolant to the refrigerant passage of the cooler; and
the refrigerant supply and discharge portion is provided with a refrigerant discharge port communicating with the refrigerant passage of the cooler so as to discharge the coolant from the refrigerant passage of the cooler.

5. The power conversion apparatus according to claim 1, wherein:
the capacitor includes a filter capacitor and a smoothing capacitor, and
the filter capacitor is placed closer to the second end face of the laminated body than the smoothing capacitor.
